(19) United States
(12) Patent Application Publication
(10) Pub. No.: US 2022/0311344 A1
(43) Pub. Date: Sep. 29, 2022

(54) Oscillator Circuit for Controlling a Transformer

(71) Applicant: Infineon Technologies AG, Neubiberg (DE)

(72) Inventor: Marcus Nuebling, Olching-Esting (DE)

(21) Appl. No.: 17/655,279

(22) Filed: Mar. 17, 2022

(30) Foreign Application Priority Data
Mar. 23, 2021 (DE) 102021107212.3

(51) Int. Cl. H02M 3/335

(52) U.S. Cl. CPC H02M 3/33523; H02M 3/33553

(57) ABSTRACT

In accordance with an embodiment, an oscillator circuit includes: a main current path coupled between a supply voltage terminal and a ground terminal, the main current path including a parallel resonant circuit, a load current path of a first transistor and a load current path of a second transistor. The parallel resonant circuit includes an inductor formed by a primary winding of a transformer, and a first capacitor; a terminal of the inductor is connected to the ground terminal; the load current path of the first transistor is coupled between the parallel resonant circuit and the load current path of the second transistor; and the parallel resonant circuit is coupled to a control electrode of the second transistor via a feedback path that includes a second capacitor.

This application claims the benefit of German Patent Application No. 102021107212.3, filed on Mar. 23, 2021, which application is hereby incorporated herein by reference.

### TECHNICAL FIELD

This description relates to an oscillator circuit for controlling a transformer such as an integrated coreless transformer.

### BACKGROUND

In order to provide galvanic isolation between two parts of an electronic circuit, transformers (single-phase transformers, often with the same number of turns on the primary and secondary sides) can be used, in particular integrated coreless transformers. To provide signal transmission via a coreless transformer, oscillator circuits are usually used, wherein a low current consumption is a design goal. Furthermore, a high CMTI (Common Mode Transient Immunity) value is desirable. In many applications, a CMTI value is specified that the circuit must have. Furthermore, integrated flat coils in particular, which are used in coreless transformers, require a comparatively high chip area. Reducing space consumption is also a design goal. The object of the invention is to improve existing designs.

### SUMMARY

The above-mentioned object is achieved by the circuit as claimed in claim 1 and the semiconductor device as claimed in claim 10. Preferred exemplary embodiments and further developments are the subject matter of the dependent claims.

One exemplary embodiment relates to an oscillator circuit. This comprises a main current path located between a supply voltage terminal and ground. The latter comprises a parallel resonant circuit, a load current path of a first transistor, and a load current path of a second transistor. The parallel resonant circuit comprises a capacitor and an inductor, which is formed by the primary winding of a transformer. One terminal of the inductor is connected to ground, and the load current path of the first transistor is located between the parallel resonant circuit and the load current path of the second transistor. The parallel resonant circuit is coupled to a control electrode of the second transistor via a feedback path which comprises a further capacitor.

### BRIEF DESCRIPTION OF THE DRAWINGS

In the following text, exemplary embodiments are described based on illustrations. The illustrations are not necessarily true to scale and the exemplary embodiments are not limited to the aspects presented. Rather, the emphasis is given to illustrating the principles underlying the exemplary embodiments. In the drawings:

FIG. 1 shows a general view of a circuit for transmitting a signal via a coreless transformer for the purpose of galvanic isolation of two circuit parts, wherein the primary side of the transformer is controlled by an oscillator;

FIG. 2 contains timing diagrams to illustrate the signals that occur in the circuit of FIG. 1’

FIG. 3 shows an exemplary application in which differential signals are transmitted via the coreless transformer;

FIG. 4 shows an example of an oscillator with differential signal output, which is suitable for the application of FIG. 3;

FIGS. 5A-5B and 6A-6C show various approaches to the design of an oscillator with single-ended signal output;

FIGS. 7A-7D show various exemplary embodiments of a novel oscillator design, which enables low power consumption, relatively low space consumption, and a high CTMI value;

FIG. 8 shows a transmitter circuit for an integrated coreless transformer with an oscillator circuit according to the design of FIG. 7; and

FIG. 9 shows an exemplary application with galvanic isolation in a chip package.

### DETAILED DESCRIPTION OF ILLUSTRATIVE EMBODIMENTS

FIG. 1 illustrates a general circuit for transmitting a signal S_{IN} via a coreless transformer 10 for the purpose of galvanically isolating two circuit parts. An oscillator is used as a transmitter circuit 11 which generates an oscillator signal from the input signal S_{IN}, the oscillator signal usually being amplitude-modulated with the input signal. A modulation technique known as on-off-keying (OOK) is commonly used, which is a special case of amplitude shift keying (ASK). Alternatively, other types of ASK or other modulation techniques can be used. The output signal of the oscillator is labeled S_{OSC} in FIG. 1. This oscillator signal S_{OSC} is transmitted via the coreless transformer 10 and received and demodulated by a suitable receiver circuit 12. The (demodulated) output signal is labeled in FIG. 1 as S_{OUT} and contains the same information as the input signal S_{IN}. In FIG. 1, a capacitor C is connected in parallel with the primary-side coil L₁. Capacitor C and coil L₁ form an LC parallel resonant circuit and, strictly speaking, are a constituent of the oscillator circuit contained in the transmitter 11.

In the example shown in FIG. 1, the oscillator/transmitter 11 generates a single-ended oscillator signal S_{OSC}, so that a terminal of the parallel oscillation circuit is connected to a first ground node GND₁ (primary-side ground), whereas a terminal of the secondary-side coil L₂ is connected to a second ground node GND₂ (secondary-side ground). The two ground nodes GND₁ and GND₂ are galvanically isolated and the voltage between the two ground potentials can vary. This means that the ground node GND₂ is floating with respect to the ground node GND₁. The receiver circuit 12 is designed to demodulate the oscillator signal S_{OSC} transmitted via the transformer 10 and to make the demodulated signal, or a signal generated from it, available as output signal S_{OUT}. Suitable receiver circuits are known per se and are therefore not explained further here.

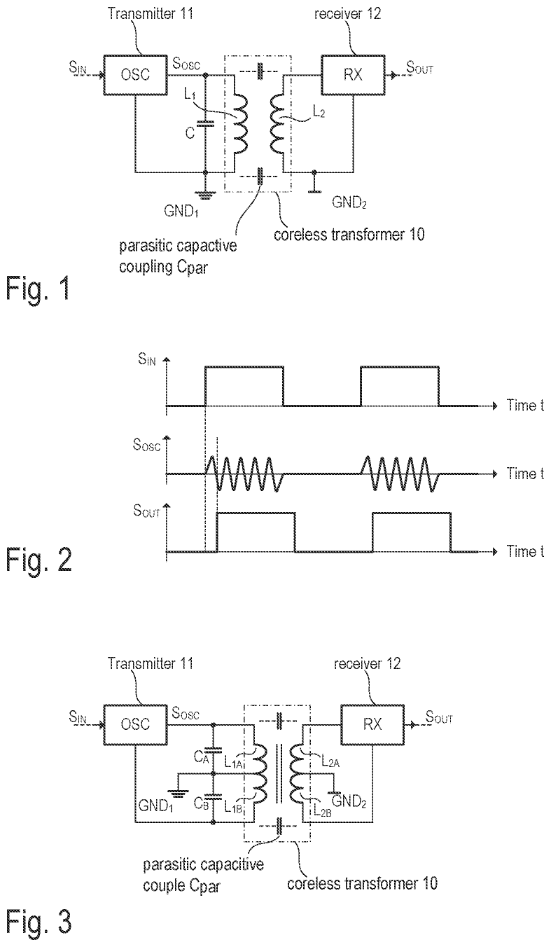

FIG. 2 illustrates typical signal traces (waveforms) of an input signal S_{IN}, of the associated oscillator signal S_{OSC} and the corresponding output signal S_{OUT}, using timing diagrams. In the example shown, the oscillator signal S_{OSC} is modulated using OOK in accordance with the input signal S_{IN}.

As mentioned above, a design goal is to achieve a low current consumption by the oscillator circuit contained in the transmitter 11, and therefore differential oscillators (push-pull oscillators) are often used, which do not generate a single-ended oscillator signal but a differential oscillator signal. In this case, the coils L₁ and L₂ (unlike in FIG. 1) are not connected at one end to the respective ground node GND₁ or GND₂, which results, however, in the system being susceptible to faults/interference due to unwanted common-mode transients caused by the rapid change in the voltage V_{GND12} between the ground nodes GND₁ and GND₂. Such a voltage change dV_{GND12}/dt leads to common-mode displacement currents through the parasitic capacitances which capacitively couple the primary side and the secondary side of the transformer 10. These common-mode displacement currents can potentially cause harmful transient voltage spikes. In FIG. 1, the parasitic capacitive coupling is labeled as C_{PAR}.

In order to compensate for the negative effect of the common-mode displacement currents, it is known to design the coils L₁ and L₂ of the coreless transformer with a middle tap. This means that the primary-side coil L₁ consists of a series circuit of two partial coils L_{1A} and L_{1B}, the common circuit node of which is connected to the first ground node GND₁. Similarly, the secondary-side coil L₂ consists of a series circuit of the two partial coils L_{2A} and L_{2B}, the common circuit node of which is connected to the second ground node GND₂. The capacitors C_{A} and C_{B} are connected in parallel with the partial coils L_{1A} and L_{1B}. The outer ends of the primary-side coil L₁ are connected to the (differential) output of a differential oscillator. This situation is shown in FIG. 3.

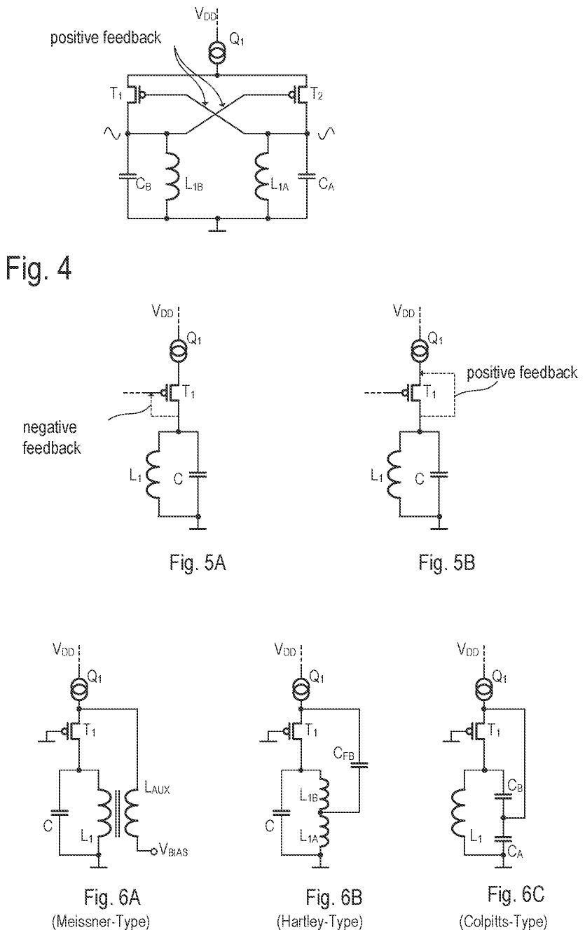

FIG. 4 illustrates a simplified example of a suitable differential oscillator. The two partial coils L_{1A} and L_{1B} together with the two capacitors C_{A} and C_{B} form two parallel resonant circuits, which are connected at one end to the ground node and at the other end to the drain electrode of a transistor T₁ or T₂ respectively, while the source electrodes of the transistors T₁, T₂ can be connected to a current source Q₁. In a simpler example, the current source can be replaced by a resistor. The gate electrodes of the transistors T₁, T₂ are connected “crosswise” to the drain electrodes of the respective other transistor, which causes positive feedback. In the example shown, the transistors are p-channel MOS transistors. In other implementations, bipolar transistors can also be used. In that case, the terms source, drain and gate should be replaced by the corresponding terms emitter, collector and base.

The circuit shown in FIG. 4 (in combination with the example in FIG. 3) has good electrical properties, i.e. low power consumption and a high CMTI. However, a consequence of the design shown in FIG. 3 is that the coreless transformer 10 integrated into a semiconductor chip requires a chip area twice as large as a coreless transformer with coils without a middle tap would need; the individual partial coils T_{1A} and T_{1B} must be integrated side by side in the metallization layers of a semiconductor die. For this reason, in the exemplary embodiments described here, transformers are used in which the primary-side and secondary-side coils do not have a middle tap. As a result, one end/terminal of the coils L₁ and L₂ must be connected to the corresponding ground nodes GND₁ or GND₂ as shown in FIG. 1, in order to ensure the required CMTI, which in turn requires an oscillator circuit with a single-ended output (as mentioned above, differential oscillators in combination with non-middle-tapped coils cannot achieve an adequate CMTI).

FIG. 5 shows two examples of oscillator circuits schematically in diagrams (a) and (b), wherein in diagram (a) the feedback of the output represents a negative feedback and in diagram (b) a positive feedback. In both cases, a parallel resonant circuit is connected between the ground nodes GND₁ and the drain terminal of a transistor T₁. The coil of the parallel resonant circuit is formed by the primary-side coil of the transformer 10 (see FIG. 1). In order to be able to oscillate continuously (i.e., in order for the resonant condition of a real impedance for the parallel resonant circuit to be met), a positive feedback is necessary, which means that the variant of diagram (a) will not work. The feedback of the oscillator output (i.e., one end of the primary-side coil L₁) must be coupled to the source terminal of the transistor. However, the source terminal of the transistor T₁ is a circuit node with low small-signal impedance (gₘ⁻¹, wherein gₘ is the transconductance of the transistor), and therefore an impedance transformation is necessary in the feedback branch in order not to degrade the Q (or quality factor) of the resonant circuit.

Various oscillator circuits with a parallel oscillation circuit connected in series with the load current path of a transistor are known. Well-known standard oscillator topologies include the Meissner oscillator, the Hartley oscillator, and the Colpitts oscillator. Examples of these are shown in FIG. 6, wherein diagram (a) shows a Meissner-type oscillator, diagram (b) shows a Hartley-type oscillator, and diagram (c) shows a Colpitts-type oscillator. The Meissner type and the Hartley type require an additional coil on the primary side of the transformer, the Meissner type because an additional transformer is required for the mentioned impedance transformation, and the Hartley type because a coil with a middle tap is required on the primary side. In both cases, the chip area requirement for the coreless transformer is doubled, which for the reasons discussed above is undesirable. The oscillator of the Colpitts type requires two high-quality metal capacitors, which also introduces unwanted additional costs. Other known types of oscillators are excluded because they are either differential oscillators (which in turn requires middle-tapped coils), or the LC parallel resonant circuit is not connected to ground at one end/terminal (which is necessary to achieve adequate CMTI). With regard to the requirement for low power consumption, a suitable oscillator topology should have only one load current path between a supply voltage node and the ground node GND₁.

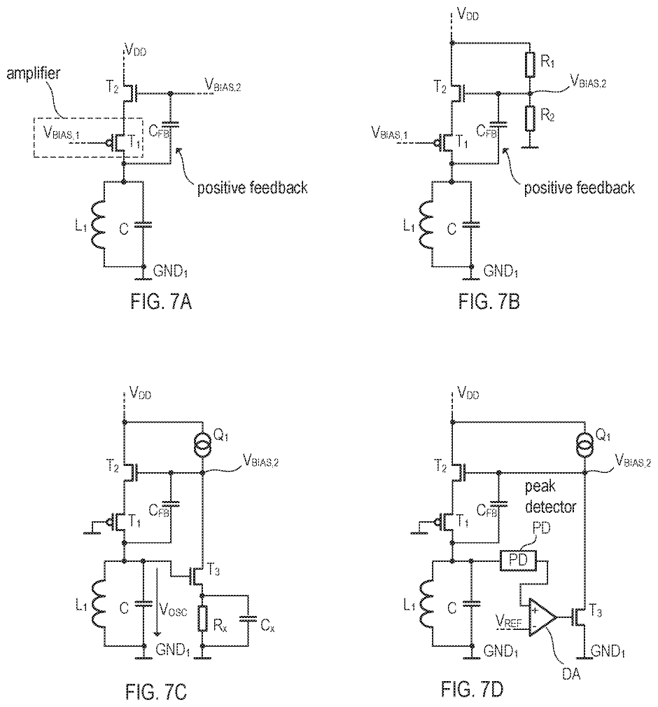

FIG. 7 illustrates in diagrams (a) to (d) various examples of variants of an oscillator circuit which meets the requirements discussed above relatively well and thus represents a good compromise with regard to the partially conflicting design goals (high CMTI, low power consumption, and small chip area). All of these examples implement positive feedback according to FIG. 5, diagram (b).

FIG. 7, diagram (a), illustrates an oscillator circuit with a (single) main current path, which is located between a supply voltage terminal (supply voltage VDD) and the ground node GND1. The main current path comprises a parallel resonant circuit, the load current path (source-drain current path in the case of MOS transistors) of a first transistor T₁ (amplifier stage), and the load current path of a second transistor T₂ (buffer stage). In the examples described here, the two transistors T₁ and T₂ have complementary transistor types. The parallel resonant circuit consists of a capacitor C and the inductor L₁ which is formed by the primary winding of a (e.g., integrated, coreless) transformer 10 (see FIG. 1). One terminal of the inductor L₁ is connected to ground (primary-side ground node GND1). The load current path of the first transistor T₁ is located between the parallel resonant circuit and the load current path of the second transistor T₂, and the parallel resonant circuit is coupled to a control electrode of the second transistor T₂ via a feedback path which comprises another capacitor C_{FB}. In the exemplary embodiment shown, the control electrode (gate electrode in MOS transistors) of the second transistor T₂ is biased with the bias voltage V_{BIAS, 2}, whereas the control electrode of the first transistor T₁ is biased with the bias voltage V_{BIAS,1}. In some exemplary embodiments, the bias voltage V_{BIAS,1} is equal to o Volt, i.e. the control electrode of the first transistor T₁ is in this case connected to the ground node GND₁.

The exemplary embodiment in FIG. 7, diagram (b), is practically identical to the example of diagram (a), with diagram (b) additionally showing an exemplary implementation of a biasing circuit which is designed to generate the bias voltage V_{BIAS,2} for the transistor T₂. In the example shown, the biasing circuit essentially comprises a voltage divider with a series circuit of resistors R₁ and R₂, which is connected between the supply voltage nodes (supply voltage V_{DD}) and the ground node GND1. At the common circuit node (i.e., at the output of the voltage divider) of the resistors R₁ and R₂ the bias voltage V_{BIAS,2} is available: V_{BIAS,2}=(R₂/(R₁+R₂)V_{DD}). The output of the voltage divider is connected to the control electrode of the transistor T₂.

The diagrams (c) and (d) in FIG. 7 show the same example as in diagram (a), wherein diagram (c) additionally shows an example of a biasing circuit which is designed to generate the bias voltage V_{BIAS,2} for the transistor T₂ depending on a level of the (oscillating) output voltage V_{OSC} (corresponding to oscillator signal S_{OSC} in FIG. 1). The example from FIG. 7, diagram (d), is a generalization of the example from diagram (c). Essentially, the biasing circuits in diagrams (c) and (d) implement an automatic gain control by adjusting the bias voltage V_{BIAS,2} so that the level of the output voltage V_{OSC} (approximately) remains at a desired value.

The biasing circuit in FIG. 7, diagram (d) comprises a peak-value rectifier (or peak detector), which is essentially formed from a transistor T₃ and an RC element (capacitor C_{X} with parallel resistor R_{X}). The peak detector is connected between the output node at which the output voltage V_{OSC} is available and the ground node GND1. The capacitor C_{X} is charged via the transistor T₃ until the capacitor voltage reaches approximately the value |V_{OSC}|-V_{TH}, i.e. the peak value of the oscillator output voltage V_{OSC}, minus the threshold voltage of the transistor T₃. The gate electrode of the transistor T₃ is connected to the output node of the oscillator, and the source electrode is connected to the RC element (C_{X}, R_{X}). The time constant R_{X}C_{X} of the RC element is longer than the period of the oscillation, so that the resistor R_{X} has no effect during operation but the capacitor C_{X} can be discharged slowly via the resistor R_{X}. In this example, the transistor T₃ is an n-channel MOS transistor. In other exemplary embodiments, an npn-bipolar transistor can be used instead. The drain terminal (or collector terminal in the case of a bipolar transistor) is connected to the control electrode of the transistor T₂. In addition, the control electrode of the transistor T₂ is also connected to a current source Q₁. This current source also supplies the load current for the transistor T₃ of the peak detector. The voltage V_{BIAS,2} on the control electrode of the transistor T₂ depends on (and varies with) the peak value of the oscillator output voltage V_{OSC} and thus stabilizes the amplitude of the oscillation.

The example from FIG. 7, diagram (d), is a generalization of the design from diagram (c). The peak detector PD supplies a voltage that represents the current peak value (amplitude) of the oscillation. The differential amplifier DA supplies an output voltage (depending on the implementation, also an output current), which represents the deviation of the oscillation amplitude from a nominal value, where the nominal value is determined by the voltage V_{REF}. The output voltage of the differential amplifier is fed to the control terminal of the transistor T₃, i.e. the transistor T₃ is activated depending on the deviation of the detected peak value from the nominal value. The drain terminal of the transistor T₃ is connected to the control terminal of the transistor T₂ and to the current source Q₁, as in the example from diagram (c). Also, in the example from diagram (c), the amplitude of the oscillation is stabilized and adjusted to the nominal value.

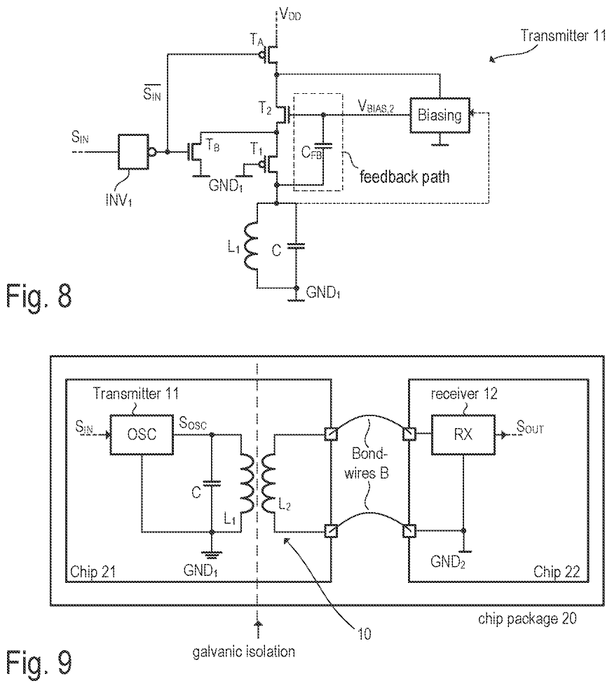

FIG. 8 illustrates a transmitter circuit for an integrated coreless transformer with an oscillator circuit according to the design from FIG. 7. The circuit is essentially the same as in FIG. 7, diagram (c), where the biasing circuit is shown as a function block. In this regard, reference is made to the above description for FIG. 7. In addition, the transmitter circuit 11 from FIG. 8 has a circuit for activating and deactivating the oscillator. This comprises the transistors T_{A} and T_{B}, wherein the control electrodes of both transistors T_{A} and T_{B} are activated with the inverted input signal S̅_̅{̅I̅N̅}̅. The transistor T_{A} is designed to connect and disconnect the main current path (parallel resonant circuit and transistors T₁ and T₂) to the supply voltage node in accordance with the input signal. The transistor T_{B} is designed to short-circuit the gate and source of transistor T₁ in accordance with the input signal and thus to deactivate the transistor T₁.

In the example shown, the transistor T_{A} is a p-channel MOS transistor and the transistor T_{B} is an n-channel MOS transistor. If the (binary) input signal S_{IN} is at a low level (i.e. a “o” is transmitted), then the inverted input signal S̅_̅{̅I̅N̅}̅ is at a high level, which means that the p-channel MOS transistor T_{A} is switched off (thus disconnecting the main current path from the power supply) and the n-channel MOS transistor T_{B} is switched on (thus deactivating the transistor T₁). If the input signal S_{IN} is at a high level (i.e. a “1” is transmitted), then the inverted input signal S̅_̅{̅I̅N̅}̅ is at a low level, which means that the p-channel MOS transistor T_{A} is switched on and the main current path is connected to the supply voltage node while the transistor T_{B} is switched off and has no effect (i.e., transistor T₁ can work normally).

In all examples from FIGS. 7 and 8, the LC parallel resonant circuit is controlled via the transistor T₁, which is operated as an amplifier stage (common gate circuit) which amplifies the feedback signal. The small-signal input impedance of the amplifier stage is relatively low, which is why the transistor T₂ is used as a buffer stage connected upstream of the amplifier stage. In the buffer stage, the transistor T₂ is operated as a common-source circuit, which has a very high input resistance and therefore implements the impedance transformation mentioned above.

FIG. 9 illustrates an exemplary application with galvanic isolation in a chip package 20. In the chip package 20 two semiconductor dies 21 and 22 are arranged. These can be mounted, for example, on a split lead frame with two parts insulated from each other. In the example shown, the transmitter 11 and the coreless transformer 10 are integrated in the first semiconductor die 21 and the receiver 12 is integrated in the second semiconductor die 22. The two dies are connected to each other by means of bond wires B. Electrically, the circuit of FIG. 8 is the same as in the example of FIG. 1 and reference is made to the above description. The galvanic isolation between the two voltage domains is formed by a (relatively thick) insulation layer between the metallization layers on the semiconductor die 21, in which layers the flat coils of the transformer are formed.

What is claimed is:

1. An oscillator circuit comprising:
a main current path coupled between a supply voltage terminal and a ground terminal, the main current path comprising a parallel resonant circuit, a load current path of a first transistor and a load current path of a second transistor,
wherein the parallel resonant circuit comprises an inductor formed by a primary winding of a transformer, and a first capacitor,
wherein a terminal of the inductor is connected to the ground terminal,
wherein the load current path of the first transistor is coupled between the parallel resonant circuit and the load current path of the second transistor, and
wherein the parallel resonant circuit is coupled to a control electrode of the second transistor via a feedback path comprising a second capacitor.

2. The oscillator circuit as claimed in claim 1, wherein the first transistor comprises a control electrode coupled to node configured to provide a dc bias voltage.

3. The oscillator circuit as claimed in claim 1, wherein the first transistor is configured to operate as an amplifier having an output coupled to the parallel resonant circuit and an input coupled to the load current path of the second transistor.

4. The oscillator circuit as claimed in claim 1, further comprising a biasing circuit configured to provide a bias voltage to a control electrode of the second transistor.

5. The oscillator circuit as claimed in claim 4, wherein the biasing circuit comprises a voltage divider configured to provide a fraction of a supply voltage applied at the supply voltage terminal as the bias voltage.

6. The oscillator circuit as claimed in claim 4, wherein the biasing circuit is configured to adjust the bias voltage depending on an output voltage applied to the parallel resonant circuit.

7. The oscillator circuit as claimed in claim 4, wherein the biasing circuit comprises a peak detector.

8. The oscillator circuit as claimed in claim 1, wherein the first transistor and the second transistor are complementary types of transistors.

9. The oscillator circuit as claimed in claim 1, further comprising a third transistor configured to disconnect the main current path from the supply voltage terminal in accordance with an input signal.

10. The oscillator circuit as claimed in claim 9, further comprising a fourth transistor configured to disable the first transistor by short-circuiting a gate of the first transistor with a source of the first transistor.

11. The oscillator circuit as claimed in claim 10, wherein a control electrode of the third transistor and a control electrode of the fourth transistor is coupled to an input signal node configured to provide the input signal.

12. A semiconductor device comprising:
a transformer integrated in a semiconductor die;
an oscillator circuit integrated in the semiconductor die, the oscillator circuit comprising:
a main current path coupled between a supply voltage terminal and a ground terminal, the main current path comprising a parallel resonant circuit, a load current path of a first transistor and a load current path of a second transistor,
wherein the parallel resonant circuit comprises an inductor formed by a primary winding of the transformer, and a first capacitor,
wherein a terminal of the inductor is connected to the ground terminal,
wherein the load current path of the first transistor is coupled between the parallel resonant circuit and the load current path of the second transistor, and
wherein the parallel resonant circuit is coupled to a control electrode of the second transistor via a feedback path comprising a second capacitor; and
a receiver circuit coupled to a secondary winding of the transformer, the receiver circuit configured to receive an output signal of the oscillator circuit received via the transformer, and to indicate a reception of the output signal of the oscillator circuit.

13. The semiconductor device of claim 12, wherein:
the first transistor comprises a first MOSFET having a drain coupled to the parallel resonant circuit and a first terminal of the second capacitor; and
the second transistor comprises second MOSFET having a source coupled to a source of the first transistor, and a gate coupled to a second terminal of the second capacitor.

14. The semiconductor device of claim 13, wherein:
the first MOSFET comprises a PMOS transistor; and
the second MOSFET comprises an NMOS transistor.

15. The semiconductor device of claim 12, further comprising:
a third transistor having a control electrode coupled to the parallel resonant circuit and an output node coupled to a control electrode of the second transistor; and
a current source having an output coupled to the output node of the third transistor.

16. The semiconductor device of claim 15, further comprising a parallel RC circuit coupled between a reference node of the third transistor and the ground terminal.

17. The semiconductor device of claim 12, wherein:
the transformer and the oscillator circuit are disposed on a first chip; and
the receiver circuit is disposed on a second chip.

18. The semiconductor device of claim 17, wherein the first chip and the second chip are disposed in a same chip package.

19. An oscillator circuit, comprising:
a transformer disposed on a chip;
a first MOSFET having a drain coupled to a primary winding of the transformer;
a second MOSFET having a source coupled to a source of the first MOSFET and a drain coupled to a supply node; and
a capacitor coupled between the drain of the first MOSFET and a gate of the second MOSFET.

20. The oscillator circuit of claim 19, further comprising a bias circuit comprising:
a peak detector having an input coupled to the drain of the first MOSFET; and
a current source coupled to an output of the peak detector and to the gate of the second MOSFET.
